(19) United States
(12) Patent Application Publication
(10) Pub. No.: US 2016/0233181 A1
(43) Pub. Date: Aug. 11, 2016

(54) ELECTRONIC DEVICE AND METHOD FOR MANUFACTURING THE SAME

(71) Applicant: FUJITSU LIMITED, Kawasaki-shi (JP)

(72) Inventors: Taiki Uemura, Kawasaki (JP); Seiki Sakuyama, Yamato (JP); Kozo Shimizu, Atsugi (JP)

(73) Assignee: FUJITSU LIMITED, Kawasaki (JP)

(21) Appl. No.: 14/994,529

(22) Filed: Jan. 13, 2016

(30) Foreign Application Priority Data
Feb. 6, 2015 (JP) 2015-021951

(51) Int. Cl. H01L 23/00

(52) U.S. Cl. CPC H01L 24/05; H01L 24/03; H01L 24/16; H01L 2224/03848; H01L 2224/0401; H01L 2224/05084; H01L 2224/05164; H01L 2924/01047; H01L 2924/01049; H01L 2924/014; H01L 2924/0132; H01L 2924/0133; H01L 2224/05109; H01L 2224/05147; H01L 2224/05155; H01L 2224/05111; H01L 2224/16145

(57) ABSTRACT

An electronic device includes a first electronic component including a first electrode, a solder provided above the first electrode, and a first bonding layer provided between the first electrode and the solder and containing Pd, Ag, and In. In another aspect of the invention, a method for manufacturing an electronic device, the method includes providing a solder containing In and Ag above a layer containing Pd and provided above an electrode of an electronic component; and melting the solder by heating to form a bonding layer containing Pd, Ag, and In between the electrode and the solder.

### CROSS-REFERENCE TO RELATED APPLICATION

This application is based upon and claims the benefit of priority of the prior Japanese Patent Application No. 2015-021951, filed on Feb. 6, 2015, the entire contents of which are incorporated herein by reference.

### FIELD

The embodiments discussed herein are related to an electronic device and a method for manufacturing the same.

### BACKGROUND

Techniques for bonding electronic components, such as a semiconductor element and a circuit board, using a solder have been known. In addition, in order to increase a bonding strength between an electrode of an electronic component and a solder bonded thereto, a technique has been known in which at a bonding portion between the electrode and the solder, an intermetallic compound containing the components of both of them is formed. For example, a method has been proposed in which between a barrier metal film formed using nickel (Ni) on a pad of copper (Cu) or the like and a solder bump containing tin (Sn), an intermetallic compound represented by Ni₃Sn₄ is formed.

Japanese Laid-open Patent Publication No. 11-307565 is an example of related art.

### SUMMARY

According to an aspect of the invention, an electronic device includes a first electronic component including a first electrode, a solder provided above the first electrode, and a first bonding layer provided between the first electrode and the solder and containing Pd, Ag, and In.

According to another aspect of the invention, a method for manufacturing an electronic device, the method includes providing a solder containing In and Ag above a layer containing Pd and provided above an electrode of an electronic component; and melting the solder by heating to form a bonding layer containing Pd, Ag, and In between the electrode and the solder.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 represents a first example of an electronic device according to a first embodiment;

FIG. 2 represents a second example of the electronic device according to the first embodiment;

FIG. 3 represents one example of an electronic device according to a second embodiment;

FIGS. 4A to 4C represent a first example of a method for manufacturing an electronic device according to the second embodiment;

FIGS. 5A to 5C represent a second example of the method for manufacturing an electronic device according to the second embodiment;

FIG. 6 represents another example of the electronic device according to the second embodiment;

FIGS. 7A to 7C represent one example of a method for manufacturing a semiconductor chip according to the second embodiment;

FIGS. 8A to 8F represent one example of cross-sectional structures of a bonding portion;

FIG. 9 represents another example of cross-sectional structures of a bonding portion;

FIGS. 10A to 10C represent examples of fracture surfaces obtained by a high speed shear test;

FIG. 11 represents one example of the results obtained by the high speed shear test;

FIG. 12 represents one example of an electronic device according to a third embodiment;

FIG. 13 represents a first example of a method for manufacturing an electronic device according to the third embodiment; and

FIG. 14 represents a second example of the method for manufacturing an electronic device according to the third embodiment.

### DESCRIPTION OF EMBODIMENTS

However, in an electronic device including electronic components bonded to each other using a solder, when an electrode and the solder are tightly bonded to each other with an intermetallic compound containing the components of both of the electrode and the solder as described in the background, when a force is applied thereto, besides the solder, the electrode and the periphery thereof may be destroyed in some cases. When the solder is only destroyed, repairs may be performed in such a way that the solder thus destroyed is melted and replaced with a new solder; however, when the electrode and the periphery thereof are destroyed, an electronic component including the electrode thus destroyed may be preferably replaced together with or without another electronic component connected the above electronic component in some cases. The replacement of an electronic component as described above may cause an increase in repair cost of the electronic device in some cases.

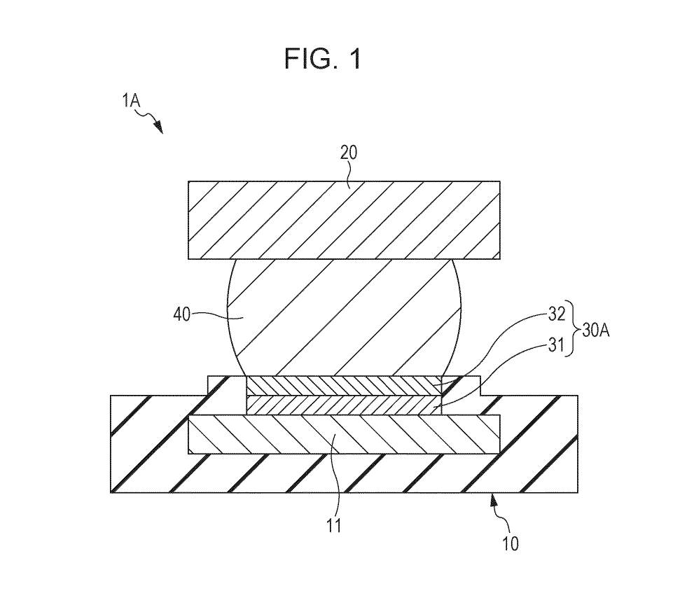

First, a first embodiment will be described. FIG. 1 represents a first example of an electronic device according to the first embodiment. FIG. 1 is a schematic cross-sectional view of an important portion of the first example of the electronic device according to the first embodiment.

An electronic device 1A illustrated in FIG. 1 includes an electronic component 10, an electronic component 20, a bonding layer 30a, and a solder 40.

The electronic component 10 includes an electrode 11. For the electrode 11, for example, copper (Cu), a material containing Cu, nickel (Ni), or a material containing Ni may be used. In addition, for the electrode 11, a laminate structure may be used which includes an electrode layer having a monolayer structure or a laminate structure and a barrier metal layer provided on the electrode layer described above.

The bonding layer 30A is provided on the electrode 11 of the electronic component 10. The bonding layer 30A illustrated in FIG. 1 by way of example includes a first layer 31 provided on the electrode 11 and a second layer 32 provided on this first layer 31.

The first layer 31 of the bonding layer 30A is a layer (PdAg-containing layer) containing palladium (Pd) and silver (Ag). The PdAg-containing layer is a layer containing Pd as a primary component and Ag. The PdAg-containing layer has a crystal structure of an alloy (a solid solution or an intermetallic compound).

The second layer 32 of the bonding layer 30A is a layer (In-containing layer) containing indium (In). The In-containing layer is a layer containing In as a primary component. The In-containing layer contains, for example, In and gold (Au). The In-containing layer has a crystal structure of an alloy (a solid solution or an intermetallic compound).

The solder 40 is provided on the bonding layer 30A. The solder 40 contains, for example, tin (Sn).

The electronic component 20 is provided to face the electronic component 10 and is electrically connected to the electronic component 10 (the electrode 11 thereof) with the solder 40 and the bonding layer 30A interposed therebetween.

In the electronic device 1A having the structure as described above, by the bonding layer 30A provided between the solder 40 and the electrode 11 of the electronic component 10, the counter diffusion of the components of the electrode 11 and the solder 40 is suppressed, and at the same time, a certain bonding force between the electrode 11 and the solder 40 is ensured.

The PdAg-containing layer, which is the first layer 31, of the bonding layer 30A provided at an electrode 11 side has a function to suppress the diffusion of Cu and Ni, which are the components of the electrode 11, to the solder 40. Furthermore, the PdAg-containing layer, which is the first layer 31, also has a function to enable the In-containing layer, which is the second layer 32, to be stably present between the solder 40 and the first layer 31.

The In-containing layer, which is the second layer 32, of the bonding layer 30A provided at a solder 40 side has a function to suppress the diffusion of Sn, which is the component of the solder 40, to the electrode 11. Furthermore, the In-containing layer, which is the second layer 32, also has a function to suppress the diffusion of Pd contained in the PdAg-containing layer, which is the first layer 31, to the solder 40. That is, the In-containing layer has a function to enable the PdAg-containing layer, which is the first layer 31, to be stably present between the electrode 11 and the second layer 32.

Since the bonding layer 30A including the first layer 31 and the second layer 32 as described above is provided between the electrode 11 and the solder 40, the counter diffusion of the components (Cu and Sn, or Ni and Sn) of the electrode 11 and the solder 40 may be suppressed. Accordingly, an intermetallic compound (such as Cu₆Sn₅, Cu₃Sn, or Ni₃Sn₄) containing the components of both of the electrode 11 and the solder 40 is suppressed from being generated therebetween. Hence, the electrode 11 and the solder 40 may be suppressed from being bonded to each other with the intermetallic compound as described above interposed therebetween.

When an electrode and a solder are bonded to each other with an intermetallic compound containing the components of both of the electrode and the solder interposed therebetween, and when a force is applied to the solder by an impact, a stress, or the like, the force is transmitted to the electrode tightly bonded to the solder with the intermetallic compound, and as a result, the electrode and the periphery thereof may be destroyed in some cases. In contrast, in the electronic device 1A described above, since the bonding layer 30A is provided between the electrode 11 and the solder 40, the intermetallic compound containing the components of both of the electrode 11 and the solder 40 may be suppressed from being generated. Accordingly, an excessive force is suppressed from being transmitted from the solder 40 to the electrode 11, and hence, the electrode 11 and the periphery thereof are suppressed from being destroyed. For example, before the electrode 11 and the periphery thereof are destroyed, the solder 40 itself, the interface between the solder 40 and the bonding layer 30A, the interface between the first layer 31 and the second layer 32 of the bonding layer 30A, the interface between the bonding layer 30A and the electrode 11, and/or the like is fractured, so that the electrode 11 and the periphery thereof are suppressed from being destroyed.

On the other hand, when an alloy, that is, an intermetallic compound, is not generated between an electrode and a solder, the solder may not be bonded to the electrode, or the bonding strength of the solder may be seriously degraded in some cases. In contrast, in the electronic device 1A described above, the bonding of the solder 40 is achieved by the bonding layer 30A (in particular, by alloy formation with the second layer 32), and hence, a certain bonding strength between the electrode 11 and the solder 40 may be ensured.

Incidentally, after electronic components are once bonded to each other using a solder, when some electronic component has a malfunction, or a solder (bonding portion) between some electrodes has a defect, such as breakage, there may be used a technique (repair technique) in which a solder bonding portion of the above electronic component is melted by heating, and a new electronic component and a new solder are substituted therefor. For example, among electronic components (a semiconductor chip, a semiconductor package, and other various types of electronic components) mounted (bonded) on a circuit board using a solder, some of the electronic components and the solder may be repaired in some cases.

In the case described above, when the solder between electrodes is only destroyed, repair may be performed by replacing the solder with a new solder by melting, and the electronic component connected thereto may be reused.

However, when the electrode and the solder are tightly bonded to each other with an intermetallic compound containing the components of both of them, and the electrode and the periphery thereof are destroyed by a force, such as an impact or a stress, at least an electronic component including the above electrode may be preferably replaced with a new component. When the destruction of the electrode portion as described above is generated at a circuit board side at which electronic components are mounted, the replacement of the circuit board or the replacement of the whole electronic device including the circuit board and the electronic components mounted thereon may be preferably performed in some cases. The replacement as described above may cause an increase in repair cost of the electronic device in some cases.

When the repair is performed, even when a solder between electrodes of electronic components included in an electronic device is destroyed, the electrodes and the peripheries thereof are preferably suppressed from being destroyed.

In the electronic device 1A illustrated in the above FIG. 1, since the bonding layer 30A is provided between the electrode 11 and the solder 40, while a certain bonding strength is ensured between the electrode 11 and the solder 40, the generation of the intermetallic compound containing the components of both of them is suppressed. Accordingly, even when a force is applied to the solder 40, since the solder 40 is formed so as to be relatively easily destroyed, an excessive force is suppressed from being transmitted to the electrode 11 from the solder 40, and hence, the electrode 11 and the periphery thereof are suppressed from being destroyed. By the structure as described above, even when the electronic device 1A has a malfunction which is preferably to be repaired, the repair may be performed while the increase in repair cost is suppressed.

Heretofore, the electronic device 1A including the bonding layer 30A which includes the PdAg-containing layer functioning as the first layer 31 and the In-containing layer formed of InAu or the like and functioning as the second layer 32 is described by way of example. In this electronic device 1A, between the first layer 31 and the second layer 32 of the bonding layer 30A, the components thereof may be slightly counter-diffused by heating in some cases. That is, in some cases, the bonding layer 30A may be formed to include a two-layer structure including a first layer 31 containing Pd as a primary component, Ag, and In and a second layer 32 containing In as a primary component and Pd. Even when the counter diffusion as described above occurs, since the bonding layer 30A containing Pd, Ag, and In is provided between the electrode 11 and the solder 40, the counter diffusion of the components of the electrode 11 and the solder 40 may be suppressed. Accordingly, as described above, the generation of the intermetallic compound containing the components of both of the electrode 11 and the solder 40 may be suppressed, and the electrode 11 and the periphery thereof are suppressed from being destroyed.

In the above FIG. 1, as a first example of the electronic device, the electronic device 1A including the bonding layer 30A having a two-layer structure including the first layer 31 containing Pd and Ag and the second layer 32 containing In is illustrated by way of example. Next, an electronic device including a bonding layer having a monolayer structure will be described as a second example.

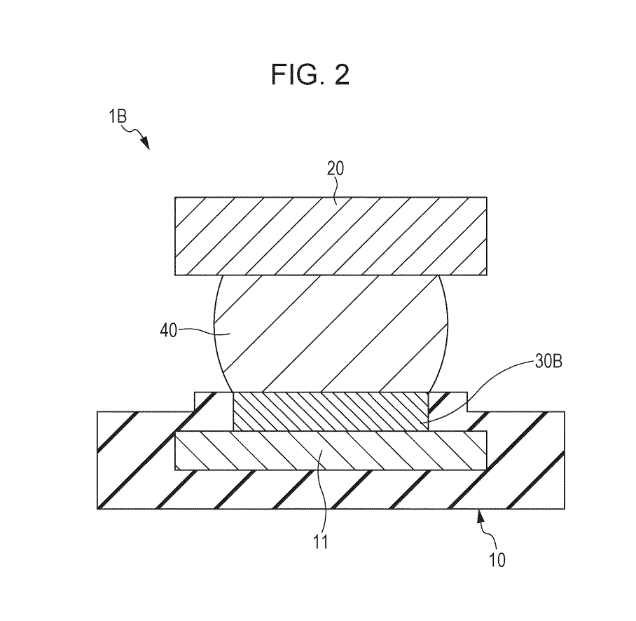

FIG. 2 represents the second example of the electronic device according to the first embodiment. FIG. 2 is a schematic cross-sectional view of an important portion of the second example of the electronic device according to the first embodiment.

An electronic device 1B illustrated in FIG. 2 includes a bonding layer 30B having a monolayer structure between the electrode 11 of the electronic component 10 and the solder 40, and this bonding layer 30B having a monolayer structure is a point different from the above electronic device 1A.

The bonding layer 30B contains Pd, Ag, and In. The bonding layer 30B is a layer containing Pd as a primary component, Ag, and In and has a crystal structure of an alloy (a solid solution or an intermetallic compound). For example, when the counter diffusion of the components of the first layer 31 and the second layer 32 of the bonding layer 30A of the above electronic device 1A progresses by heating, the bonding layer 30B is formed.

When the bonding layer 30B having a monolayer structure as described above is provided between the electrode 11 and the solder 40, the counter diffusion between the components of the electrode 11 and the solder 40 may also be suppressed. Accordingly, the generation of the intermetallic compound containing the components of both of the electrode 11 and the solder 40 may be suppressed, and the electrode 11 and the periphery thereof are suppressed from being destroyed.

In addition, for the electronic component 10 of each of the above electronic devices 1A and 1B, a semiconductor element (semiconductor chip), a semiconductor device (semiconductor package) including a semiconductor chip mounted on a circuit board, a circuit board, or the like may be used. As is the case described above, for the electronic component 20 of each of the above electronic devices 1A and 1B, a semiconductor chip, a semiconductor package, a circuit board, or the like may be used.

As the combination of the electronic component 10 and the electronic component 20 bonded thereto, for example, the combination of a semiconductor chip and a circuit board, the combination of a semiconductor package and a circuit board, and the combination of a semiconductor chip and a semiconductor package may be mentioned by way of example. In addition, as the combination of the electronic component 10 and the electronic component 20 bonded thereto, for example, there may also be mentioned the combination of semiconductor chips, the combination of semiconductor packages, and the combination of circuit boards.

The above electronic device will be described in more detail as a second and a third embodiment.

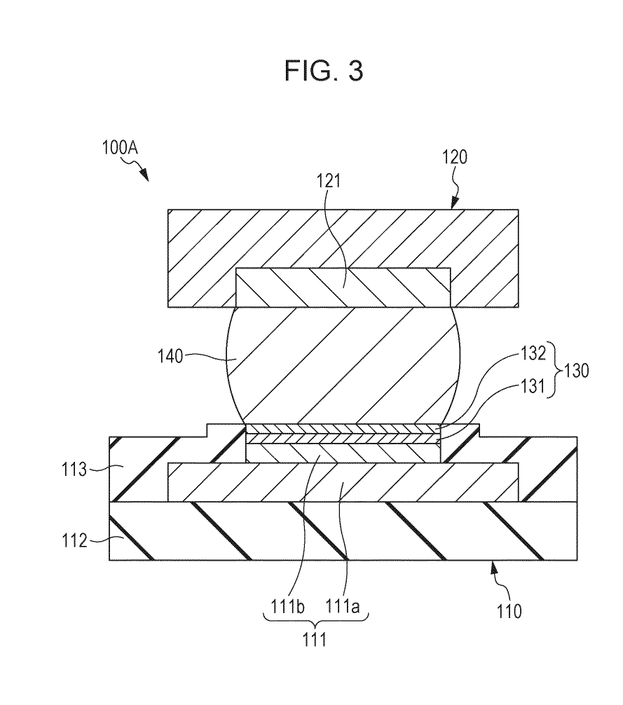

First, the second embodiment will be described. FIG. 3 represents one example of an electronic device according to the second embodiment. FIG. 3 is a schematic cross-section view of an important portion of one example of the electronic device according to the second embodiment.

An electronic device 100A illustrated in FIG. 3 includes a circuit board 110 and a semiconductor chip 120, each of which is an electronic component, and a bonding layer 130 and a solder 140.

The circuit board 110 includes a substrate 112, an electrode 111, and a protective film 113. For the substrate 112, for example, an organic insulating material, such as a glass epoxy or a polyimide, an inorganic insulating material, such as a glass or a ceramic, or a semiconductor material, such as silicon (Si), may be used. Although not illustrated in the drawing, electrically conductive portions, such as a wire and a via, are provided on and in the substrate 112, and the electrode 111 is electrically connected to the electrically conductive portions described above.

The electrode 111 includes an electrode layer 111a and a barrier metal layer 111b provided thereon. For the electrode layer 111a, for example, Cu may be used. For the electrode layer 111a, besides Cu, Ni, aluminum (Al), or the like may also be used. The electrode layer 111a may have, besides a monolayer structure, a laminate structure in which the same type of materials or different types of materials are laminated to each other.

For the barrier metal layer 111b, for example, Ni may be used. For the barrier metal layer 111b, besides Ni, Al, tantalum (Ta), titanium (Ti), tungsten (W), or a material containing at least two of the elements mentioned above including Ni may also be used. The barrier metal layer 111b may have, besides a monolayer structure, a laminate structure in which the same type of materials or different types of materials are laminated to each other.

The protective film 113 is provided on the substrate 112 so that at least a part of the electrode 111 is exposed. In this embodiment, the case in which a frame portion of the electrode layer 111a of the electrode 111 is covered with the protective film 113, and the barrier metal layer 111b is formed on a part of the electrode layer 111a which is not covered with the protective film 113 is illustrated by way of example. For the protective film 113, an insulating film, such as a solder resist, may be used.

The bonding layer 130 is provided on the electrode 111 (the barrier metal layer 111b thereof) of the circuit board 110. The bonding layer 130 includes a first layer 131 provided on the barrier metal layer 111b of the electrode 111 and a second layer 132 provided on the first layer 131.

The first layer 131 is a PdAg-containing layer containing Pd as a primary component and Ag and is, for example, a PdAg layer. The second layer 132 is an In-containing layer containing In and is, for example, an InAu layer containing In (an InAu-containing layer) as a primary component and Au. The PdAg-containing layer functioning as the first layer 131 and the In-containing layer functioning as the second layer 132 each have a crystal structure of an alloy (a solid solution or an intermetallic compound).

The solder 140 is provided on the bonding layer 130. The solder 140 contains Sn. The semiconductor chip 120 has an electrode 121. Although not illustrated in the drawing, the semiconductor chip 120 includes a circuit element, such as a transistor, formed by using a semiconductor substrate and electrically conductive portions, such as a wire and a via, electrically connected to the circuit element, and the electrode 121 is electrically connected to the electrically conductive portions as described above. The semiconductor chip 120 is provided to face the circuit board 110, and the electrode 121 and the electrode 111 are electrically connected to each other with the solder 140 and the bonding layer 130 interposed therebetween.

In addition, although a pair of electrodes, that is, the electrode 111 and the electrode 121, is illustrated in FIG. 3 by way of example, a plurality of electrodes 111 and a plurality of electrodes 121 may be provided in the circuit board 110 and the semiconductor chip 120, respectively, at positions corresponding to each other. In addition, although a pair of electronic components, that is, the circuit board 110 and the semiconductor chip 120, is illustrated in FIG. 3 by way of example, a plurality of semiconductor chips 120 may also be mounted on one circuit board 110.

In the electronic device 100A illustrated in FIG. 3, the PdAg-containing layer functioning as the first layer 131 of the bonding layer 130 and provided at an electrode 111 side suppresses the components, such as Cu and Ni, contained in the electrode 111 from being diffused to the solder 140. The In-containing layer functioning as the second layer 132 of the bonding layer 130 and provided at a solder 140 side suppresses Sn, which is the component of the solder 140, from being diffused to the electrode 111. The In-containing layer functioning as the second layer 132 suppresses Pd contained in the first layer 131 from being diffused to the solder 140.

Since the bonding layer 130 including the first layer 131 and the second layer 132 as described above is provided between the barrier metal layer 111b of the electrode 111 and the solder 140, the counter diffusion of the components (Ni, Sn, and the like) of the barrier metal layer 111b and the solder 140 may be suppressed. Accordingly, the electrode 111 (the barrier metal layer 111b) and the solder 140 may be suppressed from being bonded to each other with an intermetallic compound (such as Ni₃Sn₄ or the like) containing the components of both of the electrode 111 and the solder 140. The bonding of the solder 140 at the electrode 111 side is achieved by the bonding layer 130 (particularly, by alloy formation with the second layer 132), and a certain bonding strength between the electrode 111 and the solder 140 is ensured.

As described above, the bonding layer 130 is provided between the electrode 111 and the solder 140, and while a certain bonding strength is ensured between the electrode 111 and the solder 140, the intermetallic compound containing the components of both of them is suppressed from being generated. Accordingly, even when a force is applied to the solder 140 by an impact or the like, the solder 140 is not destroyed, and the electrode 111 and the periphery thereof may be suppressed from being destroyed by an excessive force applied thereto.

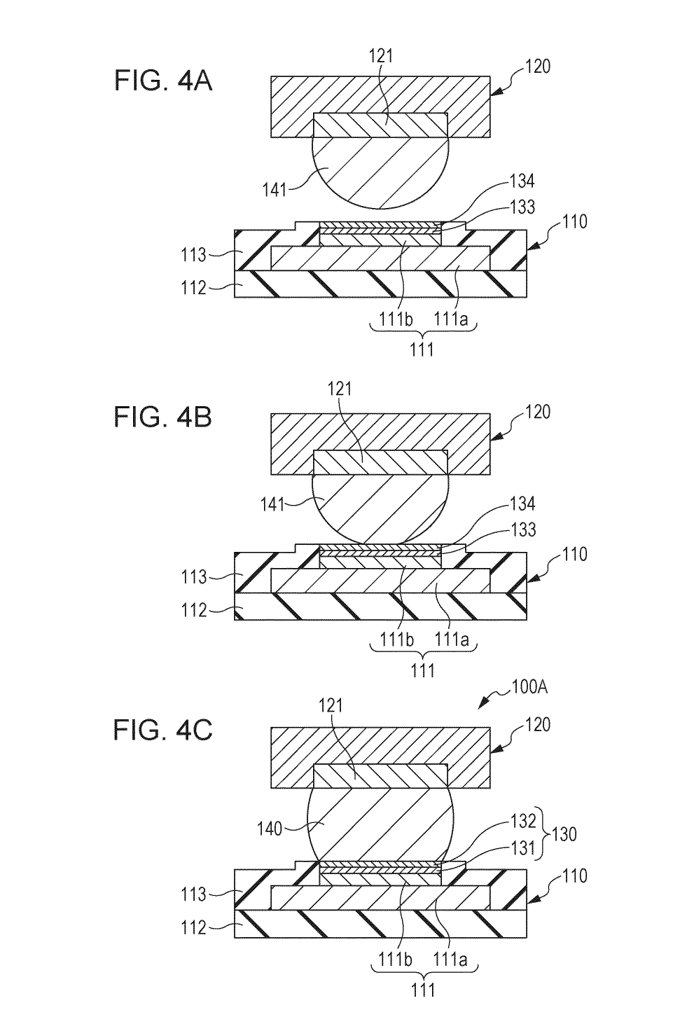

Next, one example of a method for manufacturing the electronic device 100A as described above will be described. FIGS. 4A to 4C represent a first example of a method for manufacturing an electronic device according to the second embodiment. FIG. 4A is a schematic cross-sectional view of an important portion of one example of a semiconductor chip and a circuit board before bonding. FIG. 4B is a schematic cross-sectional view of an important portion of one example of the semiconductor chip and the circuit board in bonding. FIG. 4C is a schematic cross-sectional view of an important portion of one example of the semiconductor chip and the circuit board after bonding.

First, as illustrated in FIG. 4A, the circuit board 110 and the semiconductor chip 120 are prepared. As illustrated in FIG. 4A, the circuit board 110 includes the substrate 112, the electrode 111 (the electrode layer 111a and the barrier metal layer 111b), and the protective film 113. When Ni is used for the barrier metal layer 111b provided on the electrode layer 111a of the electrode 111, the barrier metal layer 111b is formed on the electrode layer 111a to have a thickness of approximately 4 to 6 μm, for example, by electroless plating. In addition, in the case described above, the barrier metal layer 111b may contain, besides Ni, a small amount of phosphorus (P) contained in a plating solution.

On the barrier metal layer 111b of the circuit board 110 as described above, as illustrated in FIG. 4A, a Pd layer 133 and an Au layer 134 are laminated in this order. The Pd layer 133 may be formed to have a thickness of approximately 0.05 to 0.1 μm, for example, by electroless plating. The Au layer 134 may be formed to have a thickness of approximately 0.01 to 0.05 μm, for example, by electroless plating.

The semiconductor chip 120 includes the electrode 121 as illustrated in FIG. 4A. On the electrode 121, a solder 141 is mounted. For the solder 141, a solder material containing In, Ag, and Sn is used. For the solder 141, for example, a solder material containing 45 percent by weight or more of In, 0.5 percent by weight or more of Ag, and Sn as the rest may be used.

The circuit board 110 provided with the Pd layer 133 and the Au layer 134 on the barrier metal layer 111b of the electrode 111 as described above and the semiconductor chip 120 provided with the solder 141 on the electrode 121 are disposed so as to face each other as illustrated in FIG. 4A.

Subsequently, one of the circuit board 110 and the semiconductor chip 120 is disposed close to the other, and as illustrated in FIG. 4B, the solder 141 is brought into contact with the Au layer 134 and is then melted by heating. The melting of the solder 141 is performed under a relatively low temperature condition at 200° C. or less and preferably under a condition at 150° C. or less. For example, heating is performed at a temperature range of 125° C. to 150° C. so as to melt the solder 141 in contact with the Au layer 134.

When the solder 141 is melted, first, In contained in the solder 141 is surface-diffused on the Au layer 134. Ag is incorporated in the In which is surface-diffused on the Au layer 134, In and the Au layer 134 react with each other to form an InAu-containing layer, and at the same time, Ag is diffused to the Pd layer 133 to form a PdAg-containing layer. Since the Au layer 134 is the outermost surface above the electrode 111 of the circuit board 110, the surface-diffused In is allowed to react with Au, and Ag incorporated in this In may be diffused to the Pd layer 133.

By the diffusion and the reaction of the components as described above in concomitance with the melting of the solder 141, as illustrated in FIG. 4C, the bonding layer 130 including the InAu-containing layer functioning as the second layer 132 and the PdAg-containing layer functioning as the first layer 131 is formed.

As described above, the solder 141 from which In and Ag are diffused is solidified by cooling, and as a result, the solder 140 bonded to the bonding layer 130 is formed.

By the method as illustrated in those FIGS. 4A to 4C, the electronic device 100A is obtained in which the bonding layer 130 including the first layer 131, which is the PdAg-containing layer, and the second layer 132, which is the InAu-containing layer, is provided between the barrier metal layer 111b of the electrode 111 and the solder 140.

In the method described above, for the solder 141, a solder material containing 45 percent by weight or more of In, 0.5 percent by weight or more of Ag, and Sn as the rest is used, and on the surface of the electrode 111, the Pd layer 133 and the Au layer 134 are provided.

In the case described above, when the content of In contained in the solder 141 is less than 45 percent by weight, when the solder 141 is brought into contact with the Au layer 134 and is then melted, In is not sufficiently surface-diffused on the Au layer 134, and the formation of the InAu-containing layer may become difficult in some cases.

When the content of Ag contained in the solder 141 is less than 0.5 percent by weight, the amount of Ag incorporated in the In which is surface-diffused on the Au layer 134 is decreased, and the formation of the PdAg-containing layer may become difficult in some cases.

In addition, when the solder 141 is melted under a relatively high temperature condition at more than 200° C., Au and Pd are diffused from the Au layer 134 and the Pd layer 133, respectively, to the solder 141, and the formation of the bonding layer 130 having a two-layer structure including the InAu-containing layer and the PdAg-containing layer may become difficult in some cases.

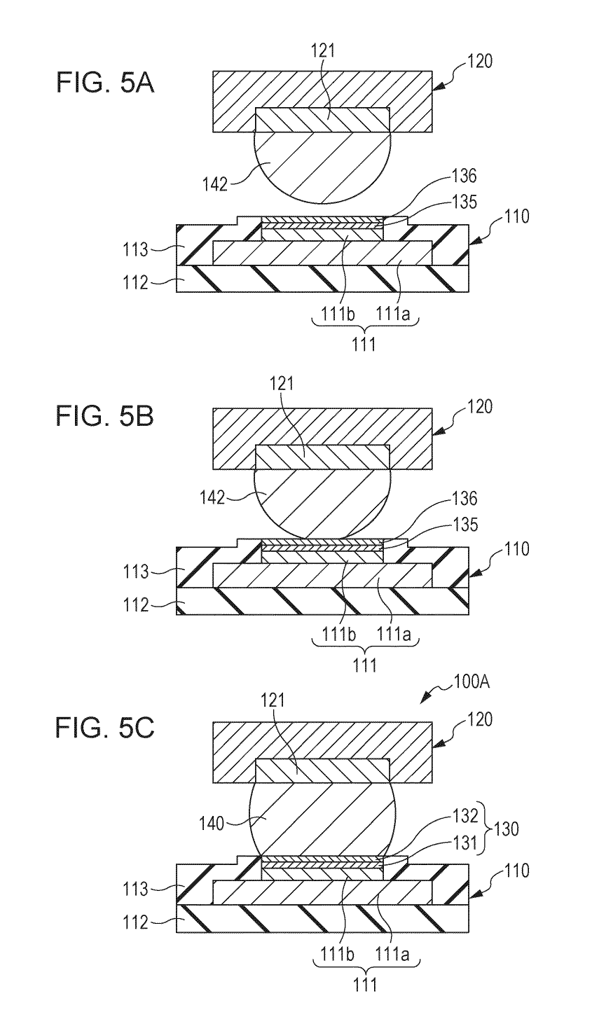

The electronic device 100A may also be manufactured by a method illustrated in FIGS. 5A to 5C. FIGS. 5A to 5C represent a second example of the method for manufacturing an electronic device according to the second embodiment. FIG. 5A is a schematic cross-sectional view of an important portion of one example of a circuit board and a semiconductor chip before bonding. FIG. 5B is a schematic cross-sectional view of an important portion of one example of the circuit board and the bonding.

By this method, as illustrated in FIG. 5A, on the barrier metal layer 111b of the circuit board 110 before bonding to the semiconductor chip 120, a PdAg layer 135 and an InAu layer 136 are laminated in this order. The PdAg layer 135 and the InAu layer 136 are each formed, for example, by electroless plating.

As illustrated in FIG. 5A, a solder 142 is mounted on the electrode 121 of the semiconductor chip 120. For the solder 142, a solder material containing Sn is used. This solder 142 may not contain In and Ag in some cases.

The circuit board 110 provided with the PdAg layer 135 and the InAu layer 136 on the barrier metal layer 111b of the electrode 111 as described above and the semiconductor chip 120 provided with the solder 142 on the electrode 121 are disposed so as to face each other as illustrated in FIG. 5A.

Subsequently, one of the circuit board 110 and the semiconductor chip 120 is disposed close to the other, and as illustrated in FIG. 5B, the solder 142 is brought into contact with the InAu layer 136 and is then melted by heating. The melting of the solder 142 is performed under a temperature condition so as to suppress the diffusion of In of the InAu layer 136 and Pd of the PdAg layer 135 to the solder 142.

When the solder 142 is melted under a predetermined temperature condition and is bonded to the InAu layer 136, as illustrated in FIG. 5C, the bonding layer 130 including the InAu layer 136 functioning as the second layer 132 and the PdAg layer 135 functioning as the first layer 131 is formed. In addition, when the solder 142 is bonded to the InAu layer 136 by melting, the counter diffusion of the components of the InAu layer 136 and the PdAg layer 135 may occur in some cases. By the diffusion as described above, the bonding layer 130 may be formed so that an InAu-containing layer is used as the second layer 132 and a PdAg-containing layer is used as the first layer 131.

The solder 142 is solidified by cooling, so that the solder 140 bonded to the bonding layer 130 is formed.

By the method illustrated in FIGS. 5A to 5C, the electronic device 100A is also obtained in which the bonding layer 130 including the first layer 131, which is the PdAg-containing layer, and the second layer 132, which is the InAu-containing layer, is provided between the barrier metal layer 111b of the electrode 111 and the solder 140.

In FIGS. 5A to 5C, although the case in which the PdAg layer 135 and the InAu layer 136 are laminated on the barrier metal layer 111b of the circuit board 110 is illustrated by way of example, a Pd layer, a Ag layer, an In layer, and an Au layer may also be laminated on the barrier metal layer 111b so as to be bonded to the solder 142. By the method as described above, the bonding layer 130 including the PdAg-containing layer and the InAu-containing layer may also be formed between the barrier metal layer 111b and the solder 140.

In addition, between the electrode 121 of the semiconductor chip 120 and the solder 140, a bonding layer including a PdAg-containing layer and an InAu-containing layer may also be provided.

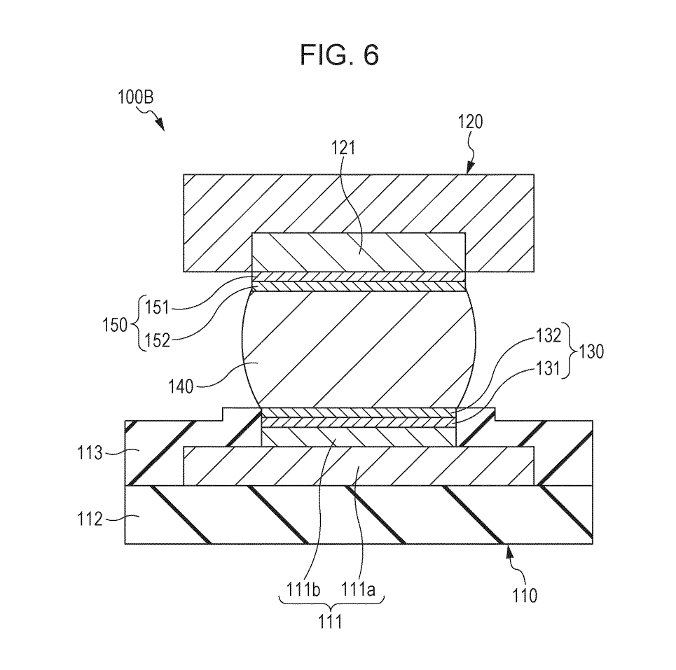

FIG. 6 represents another example of the electronic device according to the second embodiment. FIG. 6 is a schematic cross-sectional view of an important portion of the another example of the electronic device according to the second embodiment.

An electronic device 100B illustrated in FIG. 6 includes between the solder 140 and the electrode 121 of the semiconductor chip 120, a bonding layer 150 including a PdAg-containing layer functioning as a first layer 151 and an InAu-containing layer functioning as a second layer 152, and this bonding layer 150 is a point different from the electronic device 100A illustrated in FIG. 3.

The first layer 151 under the electrode 121 is a PdAg-containing layer, such as a PdAg layer, containing Pd as a primary component and Ag. The second layer 152 under the first layer 151 is an In-containing layer containing In, such as an InAu layer (InAu-containing layer) containing In as a primary component and Au. The PdAg-containing layer functioning as the first layer 151 and the In-containing layer functioning as the second layer 152 each have a crystal structure of an alloy (a solid solution or an intermetallic compound).

When the bonding layer 150 including the first layer 151 and the second layer 152 as described above is provided between the electrode 121 and the solder 140, while a certain bonding strength is ensured therebetween, an intermetallic compound containing the components of both of the electrode 121 and the solder 140 is suppressed from being generated. Accordingly, even when a force is applied to the solder 140 by an impact or the like, the solder 140 is not destroyed, and the electrode 121 and the periphery thereof may be suppressed from being destroyed by an excessive force applied thereto.

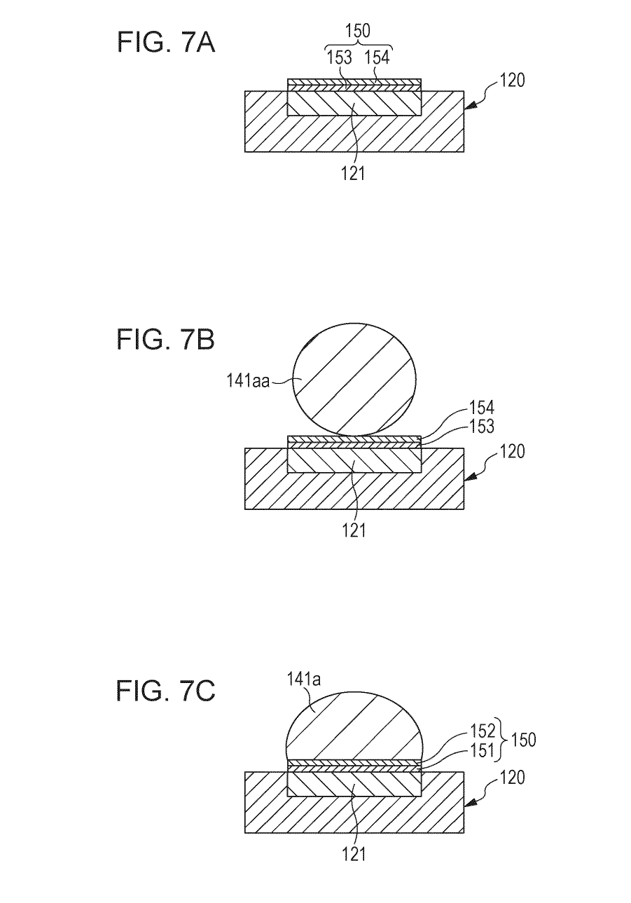

FIGS. 7A to 7C represent one example of a method for manufacturing a semiconductor chip according to the second embodiment. FIG. 7A is a schematic cross-sectional view of an important portion of one example of the semiconductor chip before bonding. FIG. 7B is a schematic cross-sectional view of an important portion of one example of the semiconductor chip in bonding. FIG. 7C is a schematic cross-sectional view of an important portion of one example of the semiconductor chip after bonding.

First, as illustrated in FIG. 7A, the semiconductor chip 120 including the electrode 121 is prepared. In accordance with the example illustrated in FIG. 4A, a Pd layer 153 and an Au layer 154 are laminated on the electrode 121 of the semiconductor chip 120 in this order as illustrated in FIG. 7A.

As illustrated in FIG. 7B, a solder 141aa having a predetermined composition condition is brought into contact with the Au layer 154 of the semiconductor chip 120 as described above and is then melted by heating. For the solder 141aa, a solder material containing In, Ag, and Sn is used, and for example, a solder material containing 45 percent by weight or more of In, 0.5 percent by weight or more of Ag, and Sn as the rest is used. The melting of the solder 141aa is performed at a relatively low temperature condition at 200° C. or less and preferably under a condition at 150° C. or less.

When the solder 141aa is melted, first, In contained in the solder 141aa is surface-diffused on the Au layer 154. Ag is incorporated in the In which is surface-diffused on the Au layer 154, the In and the Au layer 154 react with each other to form an InAu-containing layer, and at the same time, Ag is diffused to the Pd layer 153 to form a PdAg-containing layer.

By the diffusion and the reaction of the components described above in concomitance with the melting of the solder 141aa, as illustrated in FIG. 7C, the bonding layer 150 including the InAu-containing layer functioning as the second layer 152 and the PdAg-containing layer functioning as the first layer 151 is formed. The solder 141aa from which In and Ag are diffused as described above is solidified by cooling, and as a result, a solder 141a bonded to the bonding layer 150 is formed.

By the method as described above, as illustrated in FIG. 7C, the semiconductor chip 120 provided with the solder 141a which is mounted on the electrode 121 with the bonding layer 150 interposed therebetween is obtained.

For example, in accordance with the example illustrated in FIGS. 4A to 4C, when the semiconductor chip 120 on which the solder 141a is mounted as described above is bonded to the circuit board 110 provided with the Pd layer 133 and the Au layer 134 on the electrode 11, the electronic device 100B as illustrated in FIG. 6 may be obtained.

In addition, besides the method illustrated in FIGS. 7A to 7C, in accordance with the example illustrated in FIG. 5A, a method may also be used in which after a PdAg layer and an InAu layer are laminated on the electrode 121 of the semiconductor chip 120, a predetermined solder (an InSnAg solder or a solder different therefrom) is brought into contact with the laminate thus formed and is then melted by heating. Alternatively, a method may also be used in which after a Pd layer, a Ag layer, an In layer, and an Au layer are laminated on the electrode 121 of the semiconductor chip 120, a predetermined solder is brought into contact with the laminate thus formed and is then melted by heating. By the methods as described above, there may also be obtained the semiconductor chip 120 provided with the solder mounted on the electrode 121 with the bonding layer 150 including the InAu-containing layer functioning as the second layer 152 and the PdAg-containing layer functioning as the first layer 151 interposed therebetween.

In addition, although the case in which the solder (such as the solder 141a) is mounted in advance at a semiconductor chip 120 side before bonding to the circuit board 110 is described by way of example, in accordance with the example illustrated in the above FIGS. 7A to 7C, a solder may be mounted in advance at a circuit board 110 side before bonding to the semiconductor chip 120. When the circuit board 110 on which a solder is mounted in advance is prepared, this circuit board 110 and the semiconductor chip 120 mounted with or without a solder may be bonded to each other.

Next, the result of evaluation of a cross-sectional structure of a bonding portion between an electrode and a solder will be described.

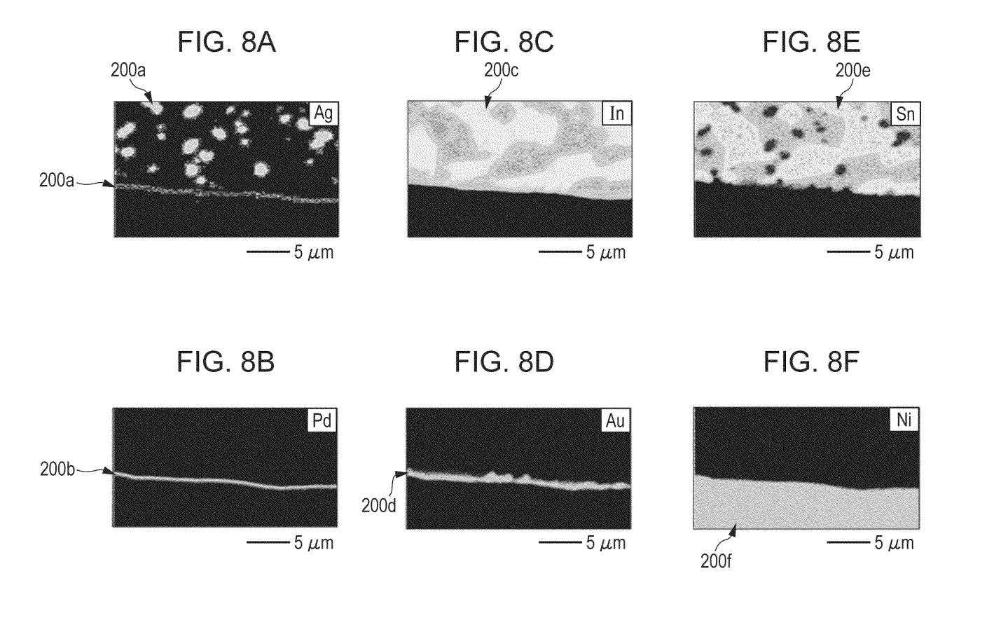

FIGS. 8A to 8F represent one example of cross-sectional structures of the bonding portion. FIGS. 8A to 8F represent the results of element analysis performed on the cross-section of the bonding portion between the electrode and the solder formed by bonding an InSnAg solder having the above composition condition onto a NiPdAu electrode at 150° C. In FIGS. 8A to 8F, when a designated element is not contained, black is displayed, and when a designated element is contained, white is displayed in accordance with the content thereof. FIG. 8A represents an analysis result of Ag, FIG. 8B represents an analysis result of Pd, FIG. 8C represents an analysis result of In, FIG. 8D represents an analysis result of Au, FIG. 8E represents an analysis result of Sn, and FIG. 8F represents an analysis result of Ni.

A region 200b in which Pd is present as illustrated in FIG. 8B is formed so as to be along an upper side of a region 200f in which Ni is present as illustrated in FIG. 8F, and corresponding to this region 200b, a region 200a in which Ag is slightly present is formed as illustrated in FIG. 8A. It is found that along the bonding portion between the electrode and the solder, a PdAg-containing layer is formed.

A region 200d in which Au is present as illustrated in FIG. 8D is formed so as to be along an upper side of this PdAg-containing layer (FIGS. 8A and 8B), and corresponding to this region 200d, In is present as illustrated in FIG. 8C. The lower side of the region 200d in which Au is present as illustrated in FIG. 8D has approximately the same shape as that of the lower side of the region 200c in which In is present as illustrated in FIG. 8C. It is found that along the bonding portion between the electrode and the solder, an InAu-containing layer is formed together with the PdAg-containing layer.

In addition, it is found that a region 200e in which Sn is present as illustrated in FIG. 8E is formed so as to be along an upper side of the region 200d in which Au is present as illustrated in FIG. 8D and that Sn is not present in a region in which the InAu-containing layer (FIGS. 8C and 8D) is present.

From FIGS. 8A to 8F, it may be concluded that at the bonding portion between the electrode and the solder, since the PdAg-containing layer and the InAu-containing layer are formed, Ni functioning as the electrode component and Sn functioning as the solder component are suppressed from being placed adjacent to each other and from being counter-diffused therebetween, and the generation of an intermetallic compound containing Ni and Sn is suppressed.

In addition, from FIGS. 8A, 8C, and 8E, it is found that in regions 200a in which Ag at a solder side is present, although In is present, Sn is not present. It may be concluded that by the manufacturing method illustrated in FIGS. 4A to 4C, since In is brought into contact with Au together with Ag, In and Au react with each other to form the InAu-containing layer, and remaining excess Ag reacts with Pd to form the PdAg-containing layer.

As described above, when the bonding layer containing Pd, Ag, and In is provided at the bonding portion between the electrode and the solder, the generation of an intermetallic compound containing the components of the electrode and the solder is suppressed. Hereinafter, the case in which at the bonding portion between the electrode and the solder, a bonding layer containing three elements, Pd, Ag, and In, is not provided will be discussed.

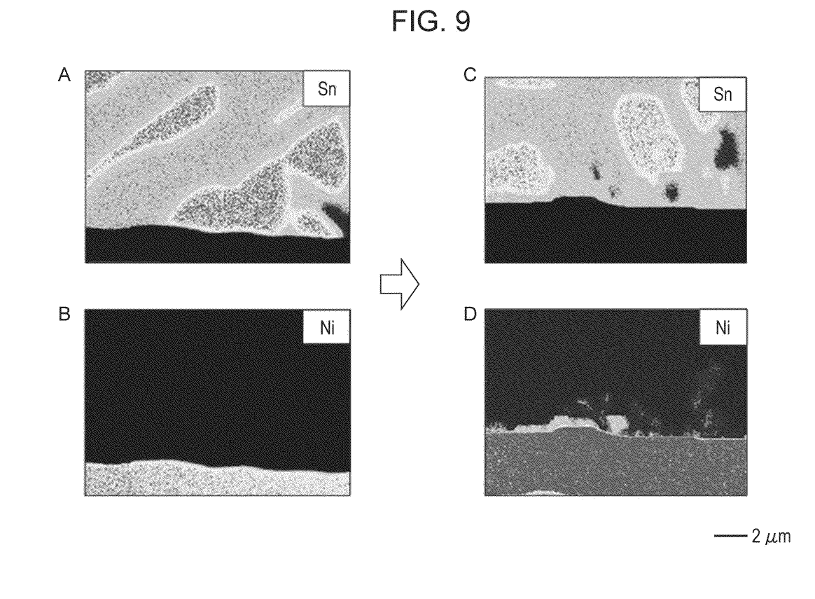

FIG. 9 represents another example of cross-section structures of a bonding portion. FIG. 9 represent the results of element analysis performed on the cross-section of the bonding portion between the electrode and the solder formed by bonding an InSnAg solder having the above composition condition onto a NiAu electrode at 150° C. In FIG. 9, when a designated element is not contained, black is displayed, and when a designated element is contained, white is displayed in accordance with the content thereof. Parts A and B of FIG. 9 represent an analysis result of Sn and that of Ni at an initial bonding stage, respectively, and Parts C and D of FIG. 9 represent an analysis result of Sn and that of Ni at a later bonding stage, respectively.

When a predetermined InSnAg solder was bonded onto a NiAu electrode, Au was diffused into the solder and was not detected. When Pd is not provided at an electrode side as described above, an InAu-containing layer is not formed at the bonding portion between the electrode and the solder. Hence, as illustrated in the parts A and B of FIG. 9, Ni functioning as the electrode component and Sn functioning as the solder component are placed adjacent to each other. When Ni functioning as the electrode component and Sn functioning as the solder component are placed adjacent to each other as described above, as illustrated in the parts C and D of FIG. 9, Ni is diffused to a solder side, and as a result, an intermetallic compound containing Ni and Sn is generated.

Pd suppresses the diffusion of Au into the solder and contributes to form an InAu-containing layer. In addition, as a result of the formation of the InAu-containing layer, a PdAg-containing layer is formed.

On the other, even when only a PdAg-containing layer is intended to be formed at the bonding portion between the electrode and the solder, it has been known that Pd is diffused into the solder, and as a result, a PdAg-containing layer may not be stably present at the bonding portion between the electrode and the solder. The InAu-containing layer suppresses the diffusion of Pd into the solder and contributes to form a PdAg-containing layer.

As described above, the PdAg-containing layer contributes to enable the InAu-containing layer to be stably present at the bonding portion between the electrode and the solder, and the InAu-containing layer contributes to enable the semiconductor chip in bonding. FIG. 5C is a schematic cross-sectional view of an important portion of one example of the circuit board and the semiconductor chip after

PdAg-containing layer to be stably present at the bonding portion between the electrode and the solder. In addition, between the PdAg-containing layer and the InAu-containing layer thus formed, the counter diffusion of the components thereof may occur in some cases. Since the bonding layer containing Pd, Ag, and In is provided at the bonding portion between the electrode and the solder, the generation of an intermetallic compound containing the components of both of the electrode and the solder may be suppressed.

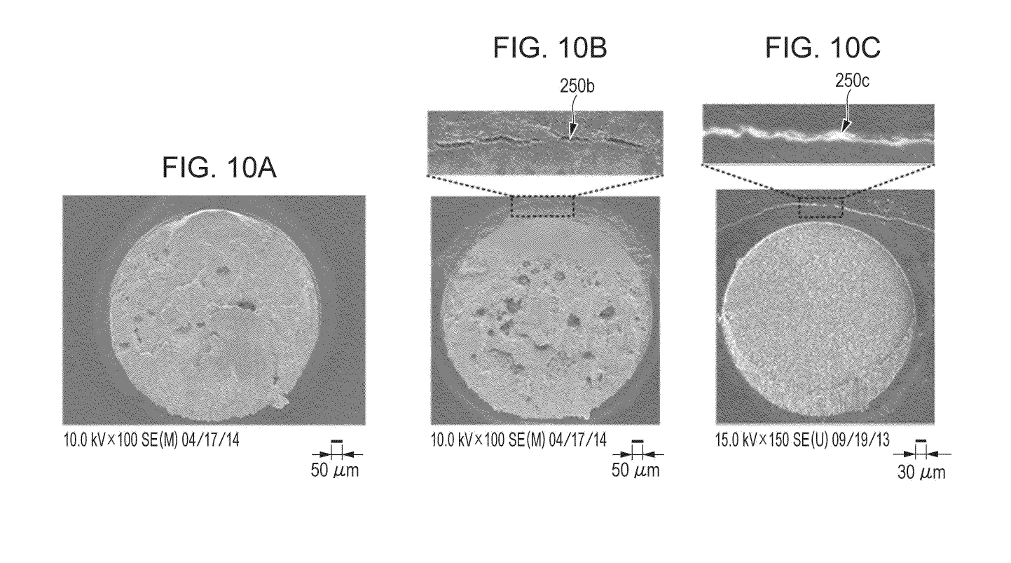

FIGS. 10A to 10C represent examples of fracture surfaces obtained by a high speed shear test.

FIGS. 10A to 10C each represent an example of a scanning electron microscope (SEM) image of the fracture surface obtained by a high speed shear test. The high speed shear test is performed at a shear speed of 3,000 mm/s on a sample formed by bonding one of an InSnAg solder, an InSn eutectic solder, and a SnAgCu solder onto a NiPdAu electrode. FIG. 10A is a SEM image of the fracture surface of the sample formed by bonding the InSnAg solder onto the NiPdAu electrode. FIG. 10B is a SEM image of the fracture surface of the sample formed by bonding the InSn eutectic solder onto the NiPdAu electrode. FIG. 10C is a SEM image of the fracture surface of the sample formed by bonding the SnAgCu solder onto the NiPdAu electrode.

In the sample in which the InSnAg solder is bonded onto the NiPdAu electrode, a PdAg-containing layer and an InAu-containing layer are formed at the bonding portion between the electrode and the solder. After a high speed shear test of this sample, as illustrated in FIG. 10A, destruction, such as crack, was not observed around the electrode.

In contrast, in the sample in which the InSn eutectic solder or the SnAgCu solder is bonded onto the NiPdAu electrode, neither a PdAg-containing layer nor an InAu-containing layer is formed at the bonding portion between the electrode and the solder. After a high speed shear test of the samples, as illustrated in FIGS. 10B and 10C, a crack 250b and a crack 250c are observed around the electrodes, respectively.

Since the PdAg-containing layer and the InAu-containing layer are formed at the bonding portion between the electrode and the solder, a bonding portion which is unlikely to be destroyed around the electrode may be formed.

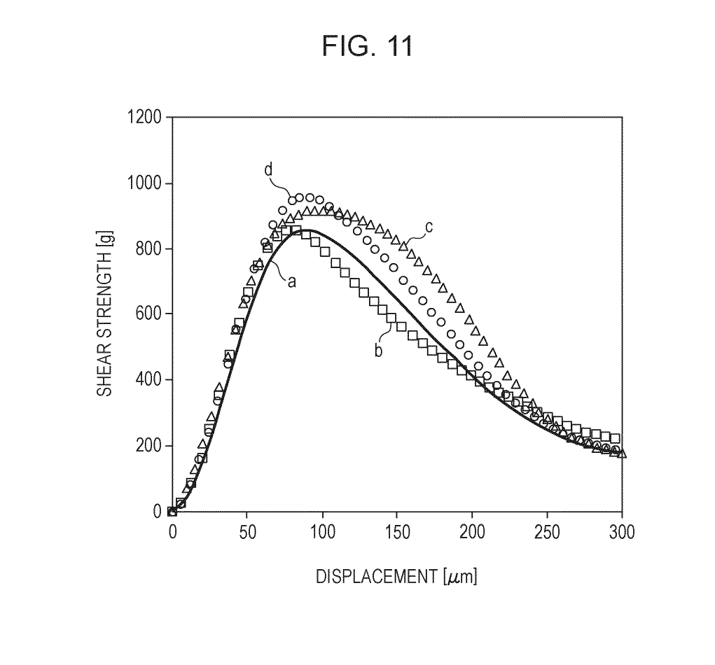

FIG. 11 represents one example of the results obtained by the high speed shear test. The vertical axis of FIG. 11 represents the shear strength [g], and the horizontal axis represents the displacement [μm]. FIG. 11 represents by way of example, the results of a high speed shear test performed on a sample obtained by holding an InSnAg solder (48 percent by weight of Sn and 1 percent by weight of Ag) on a NiPdAu electrode at 150° C. for 2 minutes or more for bonding. In addition, for the comparison purpose, FIG. 11 also represents by way of example, the results of a high speed shear test performed on samples obtained by boding an InSn solder (48 percent by weight of Sn) to a Cu electrode, a NiAu electrode, and a NIPdAu electrode. In addition, the diameter of the solder (solder bump) after boding is approximately 600 μm.

In a sample a in which the InSnAg solder is bonded to the NiPdAu electrode, a PdAg-containing layer and an InAu-containing layer are formed at the bonding portion between the electrode and the solder. In contrast, in a sample b in which the InSn solder is bonded to the Cu electrode, a sample c in which the InSn solder is bonded to the NiAu electrode, and a sample d in which the InSn solder is bonded to the NiPdAu electrode, neither a PdAg-containing layer nor an InAu-containing layer is formed at the bonding portion between the electrode and the solder. In the samples b, c, and d, at the bonding portion between the electrode and the solder, an intermetallic compound containing the components thereof, that is, Cu and Sn or Ni and Sn, is formed.

Compared to the shear strength of the sample a (solid line) in which the PdAg-containing layer and the InAu-containing layer are formed, the shear strengths of the sample b (□), the sample c (Δ), and the sample d (◯) in each of which the intermetallic compound containing the components of the electrode and the solder is formed each have a rapid rise to the peak. In addition, the shear strength of the sample a (solid line) in which the PdAg-containing layer and the InAu-containing layer are formed is ensured at a level of that of the sample b having the lowest shear strength among the sample b (□), the sample c (Δ), and the sample d (◯) in each of which the intermetallic compound containing the components of the electrode and the solder is formed.

In a range from the start of measurement to the peak of the shear strength, although the displacement of each of the sample b (□), the sample c (Δ), and the sample d (◯) is the same as that of the sample a (solid line), a larger force is applied to the bonding portion, and by the presence of the strong intermetallic compound, an excessive force is also applied to the electrode functioning as the base of the bonding portion. In contrast, in the range from the start of measurement to the peak, an increase in shear strength with respect to the displacement of the sample a (solid line) is slow as compared to that of each of the sample b (□), the sample c (Δ), and the sample d (◯), and a force applied to the electrode is reduced. Furthermore, in the sample a (solid line), a bonding portion which withstands a certain peak shear strength is realized, and a certain bonding strength may be ensured.

When the PdAg-containing layer and the InAu-containing layer are provided at the bonding portion between the electrode and the solder, while a certain bonding strength is ensured, the generation of the intermetallic compound containing the components of the solder and the electrode is suppressed, and the electrode and the periphery thereof are suppressed from being destroyed.

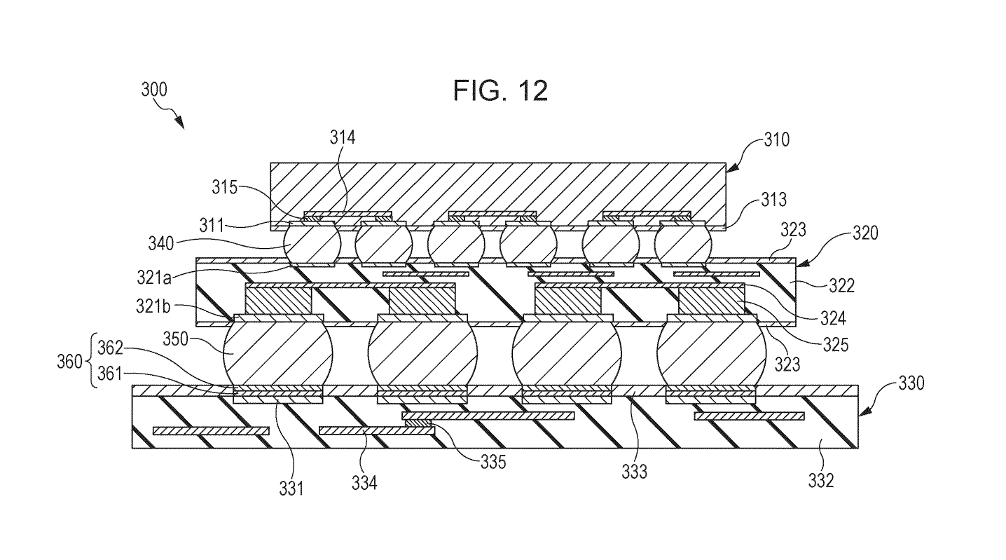

Next, a third embodiment will be described. FIG. 12 represents one example of an electronic device according to the third embodiment. FIG. 12 is a schematic cross-sectional view of an important portion of one example of the electronic device according to the third embodiment.

An electronic device 300 illustrated in FIG. 12 includes a semiconductor chip 310, an interposer 320, and a circuit board 330. The semiconductor chip 310 includes a circuit element (not illustrated), such as a transistor, formed using a semiconductor substrate; wires 314 and vias 315, each of which is an electrically conductive portion electrically connected to the circuit element; and a plurality of electrodes 311 electrically connected to the electrically conductive portions as described above. On the surface of the semiconductor chip 310, a protective film 313 is provided so that at least a part of each of the electrodes 311 is exposed.

The interposer 320 includes a substrate 322; wires 324 and vias 325 each of which is an electrically conductive portion provided in the substrate 322; and a plurality of electrodes 321a and 321b provided on the front and the rear surfaces of the substrate 322 and electrically connected to the electrically conductive portions provided therein. On the front and the rear surfaces of the interposer 320, protective films 323 are provided so that at least a part of each of the electrodes 321a and 321b is exposed. In addition, for the interposer 320, although a printed circuit board may be used, an interposer, such as a Si interposer, using a semiconductor material may also be used.

The circuit board 330 includes a substrate 332; wires 334 and vias 335, each of which is an electrically conductive portion provided in the substrate 332; and a plurality of electrodes 331 provided on the front surface of the substrate 332 and electrically connected to the electrically conductive portions provided therein. On the surface of the circuit board 330, a protective film 333 is provided so that at least a part of each of the electrodes 331 is exposed. In addition, as is a front surface side of the circuit board 330, on a rear surface side thereof, electrodes and a protective film may also be provided.

In the electronic device 300, the electrodes 311 of the semiconductor chip 310 and the electrodes 321a at the front surface side of the interposer 320 are electrically connected to each other with solders 340 provided therebetween. In addition, the electrodes 321b at the rear surface side of the interposer 320 are electrically connected to the electrodes 331 of the circuit board 330 with solders 350 provided therebetween.

For the convenience of illustration in FIG. 12, although a bonding layer 360 is only illustrated which is provided at a bonding portion between the electrode 331 of the circuit board 330 and the solder 350 and which includes a PdAg-containing layer functioning as a first layer 361 and an InAu-containing layer functioning as a second layer 362, bonding layers similar to that described above may also be provided at other bonding portions. That is, at each of a bonding portion between the electrode 311 of the semiconductor chip 310 and the solder 340, a bonding portion between the electrode 321a of the interposer 320 and the solder 340, and a bonding portion between the electrode 321b of the interposer 320 and the solder 350, a bonding layer including a PdAg-containing layer and an InAu-containing layer may also be provided.

In the case in which the electronic device 300 is manufactured, for example, the semiconductor chip 310 is mounted on the interposer 320, and the interposer 320 mounting the semiconductor chip 310 as described above is then mounted on the circuit board 330.

In this case, the mounting of the solder on the semiconductor chip 310 may be performed, for example, in accordance with the example in which the solder 141a is mounted on the semiconductor chip 120 as illustrated in FIGS. 7A to 7C. The bonding between the semiconductor chip 310 mounting the solder and the interposer 320 may be performed, for example, in accordance with the example of the bonding between the semiconductor chip 120 and the circuit board 110 as illustrated in FIGS. 4A to 4C and FIGS. 5A to 5C. The mounting of the solder on the interposer 320 may be performed, for example, in accordance with the example in which the solder 141a is mounted on the semiconductor chip 120 as illustrated in FIGS. 7A to 7C. By the use of the methods as described above, at the bonding portion between the electrode 311 of the semiconductor chip 310 and the solder 340, the bonding portion between the electrode 321a of the interposer 320 and the solder 340, and the bonding portion between the electrode 321b of the interposer 320 and the solder 350, bonding layers each including a PdAg-containing layer and an InAu-containing layer are formed.

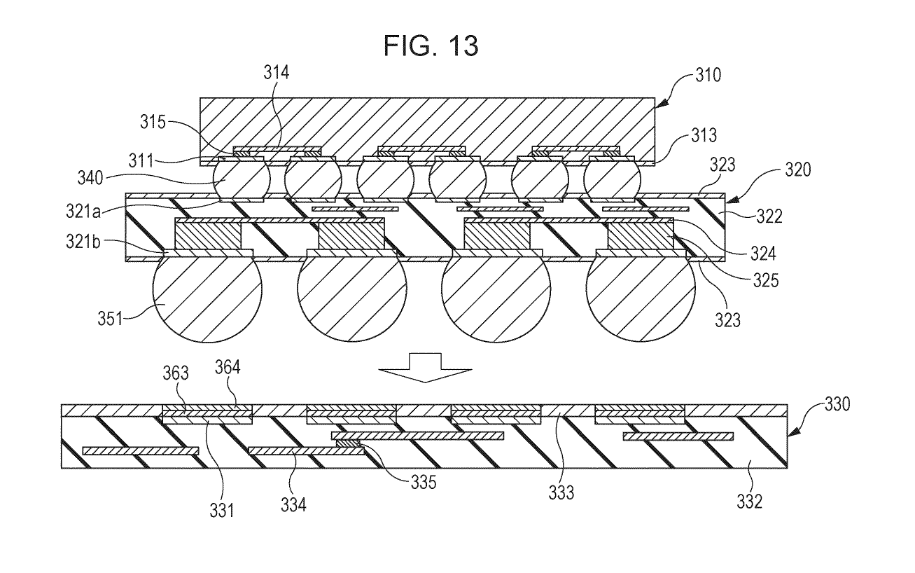

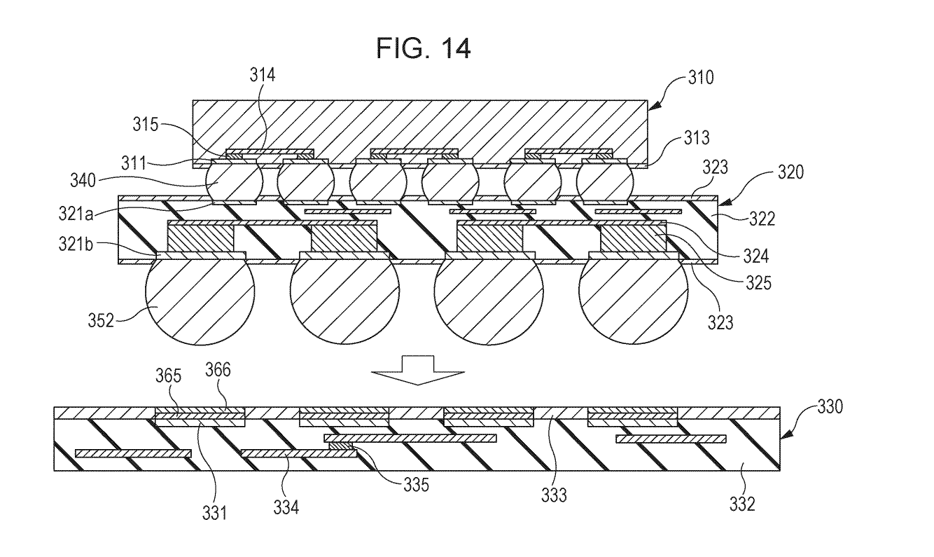

The bonding between the interposer 320 mounting the semiconductor chip 310 and the circuit board 330 may be performed as illustrated in the following FIGS. 13 and 14, for example, in accordance with the example illustrated in the above FIGS. 4A to 4C and FIGS. 5A to 5C.

FIG. 13 represents a first example of a method for manufacturing an electronic device according to the third embodiment. FIG. 13 is a schematic cross-sectional view of an important portion of one example of a step of bonding an interposer mounting a semiconductor chip to a circuit board.

For example, as illustrated in FIG. 13, on the electrode 331 of the circuit board 330, a Pd layer 363 and an Au layer 364 are laminated in this order. In addition, the interposer 320 mounting the semiconductor chip 310 and solders 351 on the front and the rear surfaces, respectively, and the circuit board 330 in which the Pd layer 363 and the Au layer 364 are laminated on each electrode 331 are disposed to face each other. For the solder 351, a solder material containing In, Ag, and Sn, such as a solder material containing 45 percent by weight or more of In, 0.5 percent by weight or more of Ag, and Sn as the rest, is used.

Subsequently, as is the example illustrated in the above FIG. 4A to 4C, the solder 351 is brought into contact with the Au layer 364, is then melted by heating at a temperature of 200° C. or less or preferably 150° C. or less, and is finally cooled. Accordingly, as illustrated in the above FIG. 12, the bonding layer 360 including the InAu-containing layer functioning as the second layer 362 and the PdAg-containing layer functioning as the first layer 361 and the solder 350 bonded to the bonding layer 360 are formed.

By the method as illustrated in FIG. 13, the electronic device 300 having the structure as illustrated in the above FIG. 12 may be obtained.

FIG. 14 represents a second example of the method for manufacturing an electronic device according to the third embodiment. FIG. 14 is a schematic cross-sectional view of an important portion of another example of the step of bonding an interposer mounting a semiconductor chip to a circuit board.

For example, as illustrated in this FIG. 14, on the electrode 331 of the circuit board 330, a PdAg layer 365 and an InAu layer 366 are laminated in this order. In addition, the interposer 320 mounting the semiconductor chip 310 and solders 352 on the front and the rear surfaces, respectively, and the circuit board 330 in which the PdAg layer 365 and the InAu layer 366 are laminated on each electrode 331 are disposed to face each other. For the solder 352, a solder material containing Sn is used, and in this case, a material containing In and Ag may not be used in some cases.

Subsequently, as is the example illustrated in the above FIG. 5A to 5C, the solder 352 is brought into contact with the InAu layer 366, is then melted by heating at a temperature at which In of the InAu layer 366 and Pd of the PdAg layer 365 are suppressed from being diffused to the solder 142, and is finally cooled. Accordingly, as illustrated in FIG. 12, the bonding layer 360 including the InAu-containing layer functioning as the second layer 362 and the PdAg-containing layer functioning as the first layer 361 and the solder 350 bonded to the bonding layer 360 are formed.

By the method as illustrated in FIG. 14, the electronic device 300 having the structure as illustrated in the above FIG. 12 may be obtained.

In addition, instead of using the method in which the PdAg layer 365 and the InAu layer 366 are laminated on the electrode 331, a method in which a Pd layer, a Ag layer, an In layer, and an Au layer are laminated may also be used.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic device comprising:
a first electronic component including a first electrode;
a solder provided above the first electrode; and
a first bonding layer provided between the first electrode and the solder and containing Pd, Ag, and In.

2. The electronic device according to claim 1,
wherein the first bonding layer includes
a first layer provided above the first electrode and containing Pd and Ag, and
a second layer provided above the first layer and containing In.

3. The electronic device according to claim 2,
wherein the first layer contains Pd as a primary component.

4. The electronic device according to claim 2,
wherein the first layer is a PdAg alloy layer or a PdAgIn alloy layer.

5. The electronic device according to claim 2,
wherein the second layer contains In as a primary component.

6. The electronic device according to claim 2,
wherein the second layer is an InAu alloy layer or an InAuPd alloy layer.

7. The electronic device according to claim 1,
wherein the first electrode contains Cu or Ni, and
the solder contains Sn.

8. The electronic device according to claim 1,
wherein the first electrode includes
an electrode layer, and
a barrier metal layer provided above the electrode layer.

9. The electronic device according to claim 1, further comprising:
a second electronic component including a second electrode which faces the first electrode with the solder interposed therebetween; and
a second bonding layer provided between the solder and the second electrode and containing Pd, Ag, and In.

10. A method for manufacturing an electronic device, the method comprising:
providing a solder containing In and Ag above a layer containing Pd and provided above an electrode of an electronic component; and
melting the solder by heating to form a bonding layer containing Pd, Ag, and In between the electrode and the solder.

11. The method for manufacturing an electronic device according to claim 10,
wherein the providing a solder includes providing the solder above the layer containing Pd with a layer containing Au interposed therebetween.

12. A method for manufacturing an electronic device, the method comprising:
providing a solder above a layer containing In and provided above an electrode of an electronic component with a layer containing Pd and Ag interposed therebetween; and
melting the solder by heating to form a bonding layer containing Pd, Ag, and In between the electrode and the solder.

13. The method for manufacturing an electronic device according to claim 12,
wherein the layer containing In contains In and Au.

14. The method for manufacturing an electronic device according to claim 10,
wherein the bonding layer includes
a first layer provided above the electrode and containing Pd and Ag, and
a second layer provided above the first layer and containing In.
